(19) United States
(12) Patent Application Publication
(10) Pub. No.: US 2026/0271434 A1
(43) Pub. Date: Sep. 10, 2026

(54) LIGHT-EMITTING ELEMENT AND LIGHT-EMITTING DEVICE

(71) Applicant: Sharp Display Technology Corporation, Kameyama City, Mie (JP)

(72) Inventors: Masataka IWASAKI, Sakai City, Osaka (JP); Yoshihiro UETA, Sakai City, Osaka (JP)

(21) Appl. No.: 19/102,551

(22) PCT Filed: Aug. 22, 2022
(86) PCT No.: PCT/JP2022/031520

§ 371 Date: Feb. 10, 2025

(51) Int. Cl. H10H 20/812; H10H 20/823

(52) U.S. Cl. CPC H10H 20/812; H10H 20/823

(57) ABSTRACT

A light-emitting element includes: an anode and a cathode; and a light-emitting layer located between the anode and the cathode, wherein the light-emitting layer includes a plurality of quantum dots including a first element that is a metal element, and a matrix material including the plurality of quantum dots and composed of two or more kinds of elements to include a second element that is located in a higher period than the first element and is not included in the plurality of quantum dots.

### TECHNICAL FIELD

The disclosure relates to a light-emitting element and a light-emitting device.

### BACKGROUND ART

PTL 1 discloses a light-emitting element in which a space between quantum dots is filled with a polymer compound.

### CITATION LIST

### Patent Literature

PTL 1: WO 2012/128173 (published on Sep. 27, 2012)

### SUMMARY

### Technical Problem

In the related art, there has been a problem that the light-emitting element has low luminous efficiency.

### Solution to Problem

A light-emitting element according to an aspect of the disclosure includes an anode and a cathode, and a light-emitting layer located between the anode and the cathode. The light-emitting layer includes a plurality of quantum dots including a first element that is a metal element, and a matrix material including the plurality of quantum dots and composed of two or more kinds of elements to include a second element that is located in a higher period than the first element and is not included in the plurality of quantum dots.

### Advantageous Effects of Disclosure

According to an aspect of the disclosure, it is possible to improve luminous efficiency of a light-emitting element.

### BRIEF DESCRIPTION OF DRAWINGS

FIG. 1 is a cross-sectional view illustrating a configuration example of a light-emitting element according to an embodiment of the disclosure.

FIG. 2 is a schematic view illustrating an example of a region between quantum dots illustrated in FIG. 1.

FIG. 3 is a schematic view illustrating another example of a region between quantum dots illustrated in FIG. 1.

FIG. 4 is a diagram showing a short periodic table based on the old IUPAC system.

FIG. 5 is a circuit diagram illustrating an equivalent circuit of the light-emitting element illustrated in FIG. 1.

FIG. 6 is a circuit diagram illustrating an equivalent circuit of the light-emitting element illustrated in FIG. 1.

FIG. 7 is a schematic view illustrating an example of a band structure of the light-emitting layer illustrated in FIG. 1.

FIG. 8 includes process cross-sectional views for describing a step of substituting a ligand coordinated to a quantum dot.

FIG. 9 is a schematic view illustrating a quantum dot dispersion liquid.

FIG. 10 is a diagram illustrating J-V characteristics of a diode element according to an example of the disclosure.

FIG. 11 is a cross-sectional view illustrating a configuration example of the light-emitting element according to an embodiment of the disclosure.

FIG. 12 is a schematic view illustrating an example of a band structure of the light-emitting layer illustrated in FIG. 11.

FIG. 13 is a plan view illustrating a configuration example of a light-emitting device according to an embodiment of the disclosure.

### DESCRIPTION OF EMBODIMENTS

### First Embodiment

### Cross-Sectional Configuration of Light-Emitting Element

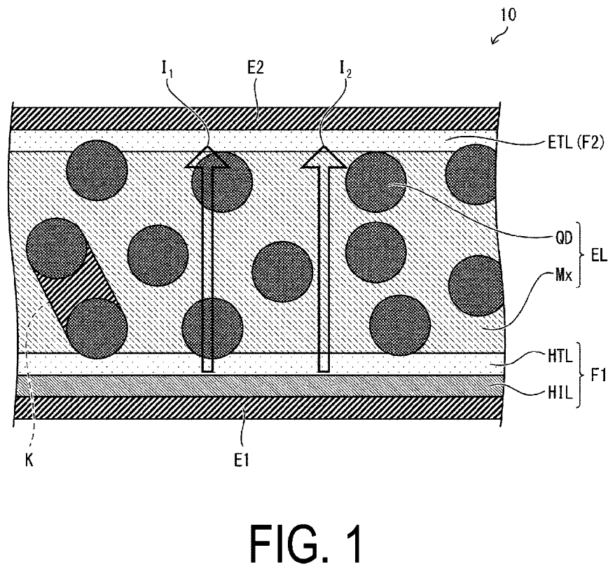

FIG. 1 is a cross-sectional view illustrating a configuration example of a light-emitting element according to an embodiment of the disclosure. As illustrated in FIG. 1, a light-emitting element 10 includes an anode E1 and a cathode E2 facing each other, and a light-emitting layer EL located between the anode E1 and the cathode E2. The light-emitting layer EL includes a plurality of quantum dots QD and a matrix material Mx. The light-emitting element 10 may further include one or both of a charge function layer F1 located between the anode E1 and the light-emitting layer EL and a charge function layer F2 located between the cathode E2 and the light-emitting layer EL. The charge function layer F1 may include any one or more of a hole injection layer HIL, a hole transport layer HTL, and an electron blocking layer. The charge function layer F2 may include any one or more of an electron injection layer, an electron transport layer ETL, and a hole blocking layer. The current flowing through the light-emitting layer EL includes a current I₁ flowing through the quantum dots QD and a current I₂ flowing while avoiding the quantum dots QD.

Each of the quantum dots QD includes at least a first element, and the first element is a metal element. The quantum dots QD may have any structure of a shell-less structure, a core-shell structure, or a multi-shell structure. The first element may be included in the cores or the shells of the quantum dots QD. The matrix material Mx is composed of two or more elements so as to include at least a second element. The second element is located in a higher period than the first element and is not included in the quantum dots QD. The matrix material Mx may be a mixed crystal of a metal sulfide containing the first element and a metal sulfide containing the second element. The first element may be Zn, and the second element may be Mg. The matrix material Mx may include a continuous film at any position in a layer thickness direction of the light-emitting layer EL, the continuous film having an area equal to or larger than 1000 nm² (excluding the cross-sectional areas of the quantum dots QD included therein) in a plane direction (the horizontal direction and the depth direction in FIG. 1) orthogonal to the layer thickness direction (the vertical direction in FIG. 1).

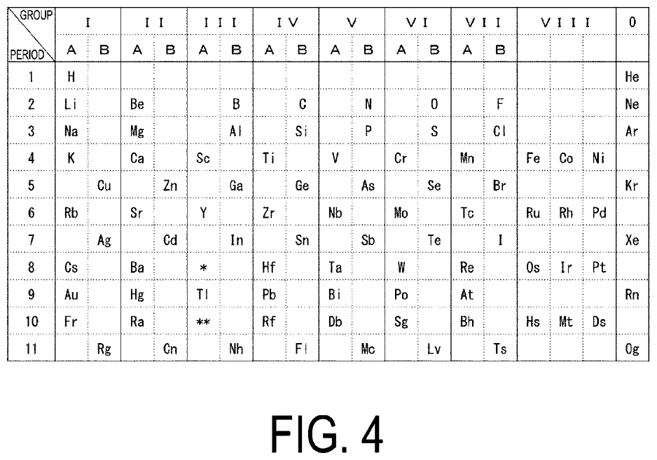

FIG. 4 is a diagram showing a short periodic table based on the old IUPAC system. In FIG. 4, “*” represents lanthanoid, and “**” represents actinoid. In the disclosure, the short periodic table shown in FIG. 4 is used for determining whether the period is the higher period, the lower period, or the same period. As shown in FIG. 4, the smaller the period number is, the higher the period is. For example, the first period including H (hydrogen) and He (helium) is the highest period.

The matrix material Mx means a member that includes and holds other objects, and can be referred to as a base material, a matrix, or a filler. The matrix material Mx may be solid at room temperature. The matrix material Mx may be a member that includes and holds the plurality of quantum dots QD. The matrix material Mx may be a constituent element of the light-emitting layer EL including the plurality of quantum dots QD.

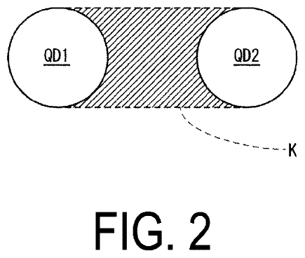

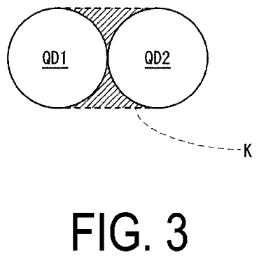

FIG. 2 and FIG. 3 are each a schematic view illustrating an example of a region between the quantum dots illustrated in FIG. 1. The matrix material Mx may be filled in the light-emitting layer EL. As illustrated in FIG. 1, focusing on two quantum dots QD among the plurality of quantum dots QD, the matrix material Mx may be configured to fill a region (space) K between the two quantum dots QD. As illustrated in FIG. 2 and FIG. 3, the two quantum dots QD are referred to as a first quantum dot QD1 and a second quantum dot QD2. In a cross-sectional view, the region K is a region surrounded by two straight lines (external common tangent) in contact with the outer peripheries of the first and second quantum dots QD1 and QD2 and the facing outer peripheries of the first and second quantum dots QD1 and QD2. As illustrated in FIG. 3, even when the first quantum dot QD1 is close to the second quantum dot QD2, the region K can exist. “Filling a space between the plurality of quantum dots” means filling a space between two quantum dots as illustrated in FIG. 2 (or FIG. 3). The matrix material Mx may be configured to fill a region (space) other than the plurality of quantum dots QD in the light-emitting layer EL. The light-emitting layer EL may include a quantum dot group including the plurality of quantum dots QD, and the matrix material Mx may be configured to fill a region (space) other than the quantum dot group. Here, three or more quantum dots QD are collectively referred to as a quantum dot group. The matrix material Mx may fill a region (space) other than the plurality of quantum dots QD in the light-emitting layer EL.

The outer edge (upper surface and lower surface) of the light-emitting layer EL may be covered with the matrix material Mx. Alternatively, a portion of the matrix material Mx may be located from the outer edge of the light-emitting layer EL, and the quantum dots QD may be located away from the outer edge. The outer edge of the light-emitting layer EL is not formed by only the matrix material Mx, and a part of the quantum dots QD may be exposed from the matrix material Mx. The matrix material may be indicated as a portion of the light-emitting layer EL excluding the plurality of quantum dots QD.

The matrix material Mx may include the plurality of quantum dots QD. The matrix material Mx may be formed so as to fill spaces formed between the plurality of quantum dots QD. The plurality of quantum dots QD may be embedded in the matrix material Mx at intervals.

The matrix material Mx may include a continuous film having an area equal to or larger than 1000 nm² in a plane direction orthogonal to the layer thickness direction. The continuous film means a film that is not separated by a material other than a material constituting the continuous film in one plane. The continuous film may be in the form of an integrated film connected without interruption by chemical bonding of the material constituting the matrix material Mx.

The matrix material Mx may be the same material as the shell included in each of the plurality of quantum dots QD. In this case, an average distance between cores adjacent to each other (core-to-core distance) may be equal to or greater than 3 nm or may be equal to or greater than 5 nm. Alternatively, the average distance between cores adjacent to each other may be 0.5 times or more the average core diameter. The core-to-core distance is obtained by averaging the shortest distances between 20 adjacent cores. The core-to-core distance may be kept wider than the distance when the shells are in contact with each other. The average core diameter is obtained by averaging the core diameters of 20 adjacent cores in the cross-sectional observation. The core diameter can be a diameter of a circle having the same area as the core area in the cross-sectional observation.

A concentration of the matrix material Mx in the light-emitting layer EL is, for example, an area ratio occupied by the matrix material Mx in a cross section of the light-emitting layer EL. This concentration may be 10% or more and 90% or less, or 30% or more and 70% or less in the cross-sectional observation. The concentration may be measured, for example, from an area ratio in image processing in the cross-sectional observation. When the quantum dots QD have a core-shell structure, the concentration of the shell may be 1% or more and 50% or less. When the shell and the matrix material Mx have the same material (same composition) and the shell and the matrix material Mx cannot be distinguished from each other, the concentration of the region including the shell and the matrix material Mx may be in a numerical range obtained by adding the numerical range of the concentration of the shell to the numerical range of the concentration of the matrix material Mx. The ratio of the core and the shell of the quantum dot QD, and the matrix material Mx may be adjusted so that the total is 100% or less as appropriate. As described above, when the shell and the matrix material Mx cannot be distinguished from each other, the shell may be regarded as a part of the matrix material Mx.

The light-emitting layer EL may be composed of the plurality of quantum dots QD and the matrix material Mx. The intensity of carbon detected by the chain structure of carbon when the light-emitting layer EL is analyzed may be equal to or less than noise level.

It is desirable that the constituent material of the matrix material Mx has a wider band gap than the constituent material (for example, the core material) of the quantum dots QD. As the constituent material of the matrix material Mx, a semiconductor or an insulator can be used. Examples of the constituent material of the matrix material Mx include, for example, a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium gallium sulfide (MgGa₂S₄). The metal oxide may be zinc oxide (ZnO), titanium oxide (TiO₂), tin oxide (SnO₂), tungsten oxide (WO₃), and zirconium oxide (ZrO₂). Note that a chemical formula written within parentheses after a compound name is a representative example. In addition, the composition ratio described in the chemical formula is desirably stoichiometry in which the actual composition of the compound is the same as the chemical formula but is not necessarily stoichiometry.

The structure of the matrix material Mx described above need not be observed over the entire area of the light-emitting layer EL as long as the structure described above is obtained by observing the cross section of the light-emitting layer EL in the range of about 100 nm. The matrix material Mx may contain a substance different from the main material (for example, an inorganic compound such as an inorganic semiconductor), for example, as an additive.

The first element and the second element may be homologous. In the disclosure, the short periodic table shown in FIG. 4 is used for determining whether they are homologous. The group numbers in the old IUPAC system are consistent with the formal number of valence electrons. Thus, in other words, the number of valence electrons of the first element may be the same as the number of valence electrons of the second element.

Referring again to FIG. 4, the group I elements include the group IA elements and the group IB elements. The group IA elements are homologous to each other, the group IB elements are homologous to each other, and the group IA elements are homologous to the group IB elements. In short, the group I elements are homologous to each other. Similarly, the group II elements are homologous to each other, the group III elements are homologous to each other, the group IV elements are homologous to each other, the group V elements are homologous to each other, the group VI elements are homologous to each other, the group VII elements are homologous to each other, and the group VIII elements are homologous to each other.

Alternatively, the group including the first element and the group including the second element may be adjacent to each other. In the disclosure, the short periodic table shown in FIG. 4 is used for determining whether two groups are adjacent to each other. In other words, the difference between the number of valence electrons of the first element and the number of valence electrons of the second element may be 1.

Referring again to FIG. 4, Group IA is adjacent to Group IIA, Group IA is adjacent to Group IIB, Group IB is adjacent to Group IIA, and Group IB is adjacent to Group IIB. In short, Group I is adjacent to Group II. Similarly, Group II is adjacent to Group III, Group III is adjacent to Group IV, Group IV is adjacent to Group V, Group V is adjacent to Group VI, Group VI is adjacent to Group VII, and Group VII is adjacent to Group VIII.

### Equivalent Circuit of Light-Emitting Element

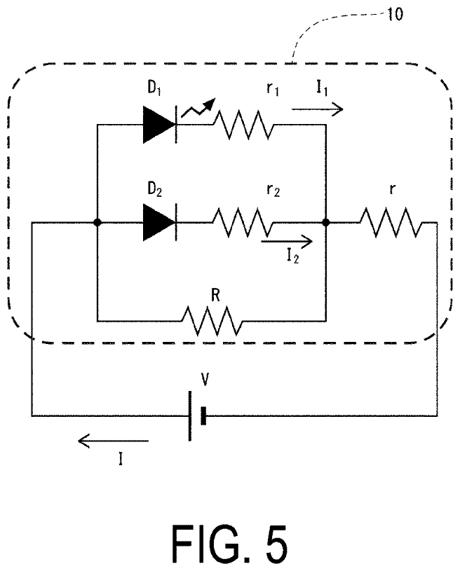

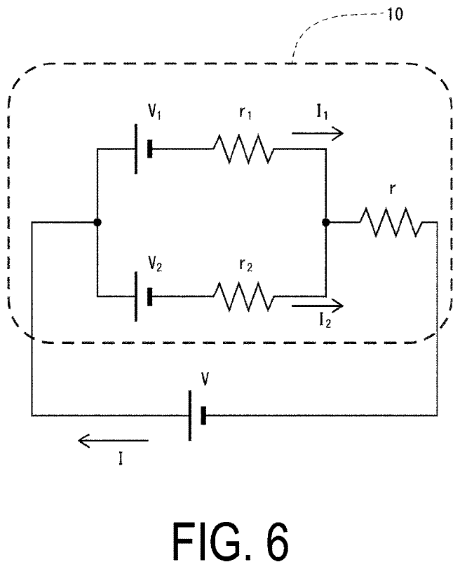

FIG. 5 and FIG. 6 are each a circuit diagram illustrating an equivalent circuit of the light-emitting element illustrated in FIG. 1. As illustrated in FIG. 5, the light-emitting element 10 is connected to a power supply voltage V and includes a light-emitting diode element Di and a non-light-emitting diode element D₂. An electrical resistance r₁ represents the electrical resistance of the light-emitting diode element D₁, and an electrical resistance r₂ represents the electrical resistance of the non-light-emitting diode element D₂. An electrical resistance R is connected in parallel to the diode elements D₁ and D₂, and indicates an electrical resistance of a path through which a leakage current flows. An electrical resistance r is connected in series to the diode elements D₁ and D₂ and indicates a wiring line resistance or the like.

The current I₁ flowing through the quantum dots QD corresponds to the current I₁ flowing through the light-emitting diode element D₁ and contributes to the light emission of the light-emitting element 10. The current I₂ flowing while avoiding the quantum dots QD corresponds to the current I₂ flowing through the non-light-emitting diode element D₂, and does not contribute to the light emission of the light-emitting element 10. A ratio of the current I₁ injected into the quantum dots QD to a current I (=I₁+I₂) flowing through the light-emitting layer EL is I₁/(I₁+I₂) and is referred to as “current injection efficiency”.

A typical light-emitting element is designed so that the electrical resistance R exhibits a high resistance value of several tens of MΩ or more. Therefore, a leakage current flowing through the electrical resistance R is normally negligibly small, and the flow path through the electrical resistance R may be ignored. The electrical resistance r is on the order of several hundreds of Q or less.

The diode elements D₁ and D₂ become conductive when a voltage equal to or higher than a so-called “turn-on voltage” is applied thereto, and the currents I₁ and I₂ flow through the diode elements D₁ and D₂. When the drive threshold voltage is applied to the light-emitting element 10 and the light-emitting element 10 emits light, both of the diode elements D₁ and D₂ are conductive. The transient characteristics in the vicinity of the turn-on voltage of each of the diode elements D₁ and D₂ have a small influence on the electrical characteristics and the light-emission characteristics of the light-emitting element 10 in a state where both of the diode elements D₁ and D₂ are conductive. Turn-on voltages V₁ and V₂ of the diode elements D₁ and D₂ have opposite polarities relative to the power supply voltage.

Therefore, the equivalent circuit illustrated in FIG. 5 can be redrawn to the equivalent circuit illustrated in FIG. 6. The following Equation (1) and Equation (2) are obtained by applying the Kirchhoff's current law to FIG. 6. The electrical characteristics of the diode elements D₁ and D₂ can be described by the Shockley diode equation shown in the following Equation (3) and depend on the saturation current.

$$\begin{matrix}[ Equation 1 ] & \\ {I}_{1} = \frac{{r}_{2} ( V - {V}_{1} ) - r ( {V}_{1} - {V}_{2} )}{{r}_{1} {r}_{2} + r ( {r}_{1} + {r}_{2} )} & ( 1 )\end{matrix}$$

$$\begin{matrix}[ Equation 2 ] & \\ {I}_{2} = \frac{{r}_{2} ( V - {V}_{2} ) - r ( {V}_{1} - {V}_{2} )}{{r}_{1} {r}_{2} + r ( {r}_{1} + {r}_{2} )} & ( 2 )\end{matrix}$$

$$\begin{matrix}[ Equation 3 ] & \\ {I}_{D} = {I}_{0} [ exp \{ \frac{{q V}_{D}}{nkR} \} - 1 ] & ( 3 )\end{matrix}$$

Wherein
I_{D}: current flowing through diode element,
I₀: saturation current,
q: elementary charge,
V_{D}: applied voltage,
n: diode coefficient,
k: Boltzmann constant, and
T: temperature. When Equation (3) is applied to diode element D₁, current I_{D}=current I₁, and when Equation (3) is applied to diode element D₂, current I_{D}=current I₂.

The saturation current depends on the intrinsic carrier density as shown in the following Equation (4). The intrinsic carrier density depends on the band gap as shown in the following Equation (5).

$$\begin{matrix}[ Equation 4 ] & \\ {I}_{0} = S \cdot q \cdot {n}_{i} \frac{( {x}_{p} + {x}_{n} )}{2 {τ}_{r}} & ( 4 )\end{matrix}$$

$$\begin{matrix}[ Equation 5 ] & \\ {n}_{i} = \sqrt{{N}_{c} {N}_{v}} exp ( - \frac{Eg}{2 kT} ) & ( 5 )\end{matrix}$$

Wherein
S: bonding area,
n₁: intrinsic carrier density,
xₚ+xₙ: depletion layer width,
τᵣ: recombination lifetime,
N_{C}: effective density of states of donor,
N_{V}: effective density of states of acceptor, and
Eg: band gap.

The physical properties of the material are reflected in the saturation current I₀ by the effective density of states N_{C}, N_{V} and the band gap Eg. The saturation current simply depends on the band gap as shown in the following Expression (6).

$$\begin{matrix}[ Equation 6 ] & \\ {I}_{0} ∝ exp ( - {E}_{g} / 2 kT ) & ( 6 )\end{matrix}$$

In general, an energy gap Eg_{ABC} in a mixed crystal ABC in which a compound BC composed of an element B and an element C is mixed with a compound AC composed of an element A and the element C exhibits a downwardly convex nonlinear relationship relative to a ratio X_{A} of the compound AC, as represented by the following Equation (7). α, β, and γ are parameters determined according to the elements A, B, and C. It is to be understood that the “element B” in this paragraph does not mean B (boron) and the “element C” does not mean C (carbon). The “element A”, the “element B” and the “element C” described in this paragraph are merely tentative names of three elements.

$$\begin{matrix}[ Equation 7 ] & \\ {E}_{gABC} = {α x}_{A} + {{β x}_{A}}^{2} + γ & ( 7 )\end{matrix}$$

This nonlinear relationship is caused by a change in the valence electron density distribution due to a difference in electronegativity or ionic radius of each element forming the mixed crystal. Therefore, it is possible to linearly approximate a mixed crystal containing elements whose electronegativities are close to each other and whose ionic radii are close to each other. For example, Mg (magnesium) and Zn (zinc) have near electronegativities and ionic radii, and the electronegativity of Mg is about 1.31 and the electronegativity of Zn is about 1.65. For many of the group II-VI compounds, including ZnS and MgS, it has been found experimentally that the effective density of states nᵢ is 10¹⁹ cm⁻³ or more. Therefore, the mixed crystal MgZnS of MgS (magnesium sulfide) and ZnS (zinc sulfide) can be linearly approximated as shown in the following Equation (8).

$$\begin{matrix}[ Equation 8 ] & \\ {E}_{gMgZnS} = {E}_{gZnS} + ( {E}_{gMgS} - {E}_{gZnS} ) {x}_{Mg} & ( 8 )\end{matrix}$$

Wherein
Eg_{MgZnS}: energy gap of mixed crystal MgZnS,
Eg_{ZnS}: energy gap of ZnS,
Eg_{MgS}: energy gap of MgS, and
X_{Mg}: ratio of MgS in mixed crystal MgZnS.

### Band Structure of Light-Emitting Layer

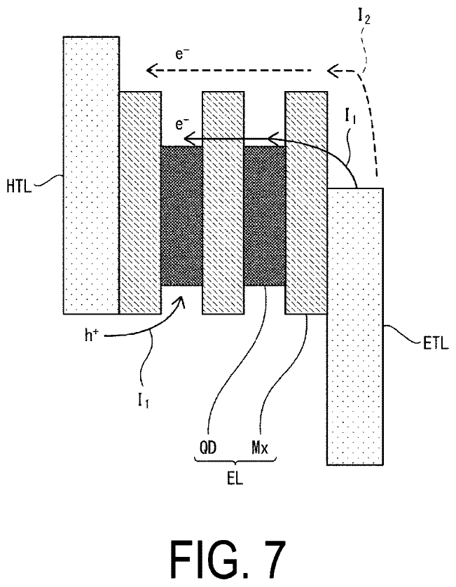

FIG. 7 is a schematic view illustrating an example of a band structure of the light-emitting layer illustrated in FIG. 1. In FIG. 7, the highest occupied molecular orbital (HOMO) and the lowest unoccupied molecular orbital (LUMO) of each of the hole transport layer HTL, the matrix material Mx, the quantum dots QD, and the electron transport layer ETL, and the band gap therebetween are indicated by rectangles. As illustrated in FIG. 7, the band gap of the matrix material Mx is larger than the band gap of the quantum dots QD. Typically, higher period elements tend to have weaker inner-core shielding of the atomic nucleus by electrons and to bond strongly with surrounding elements. As a result, a material containing an element in the higher period tends to have a deeper valence band (VBM) and a shallower conduction band (CBM) than a material containing an element in the lower period, and thus tends to have a larger band gap. In the disclosure, “VBM or CBM is deep” means that the difference in energy level of the lowest unoccupied molecular orbital (LUMO) or highest occupied molecular orbital (HOMO) relative to vacuum is large. In addition, “VBM or CBM is shallow” means that the difference in energy level of the LUMO or HOMO relative to vacuum is small.

As indicated by solid arrows in FIG. 7, with respect to the current I₁ contributing to light emission, electrons are injected from the CBM of the electron transport layer ETL into the CBM of the quantum dots QD, and holes are injected from the VBM of the hole transport layer HTL into the VBM of the quantum dots QD. Then, the electrons and the holes are recombined in the quantum dots QD to excite the quantum dots QD. The excited quantum dots QD emit light.

On the other hand, as indicated by dashed arrows in FIG. 7, electrons are injected from the CBM of the electron transport layer ETL into the CBM of the matrix material Mx with respect to the current I₂ not contributing to light emission. The CBM of the matrix material Mx is shallower than the CBM of the quantum dots QD. For this reason, electrons are hardly injected into the matrix material Mx. In addition, the turn-on voltage of the non-light-emitting diode element D₂ is higher than that of the light-emitting diode element D₁. In addition, the difference in band gap between the matrix material Mx and the quantum dots QD affects the current injection efficiency, and the larger the band gap of the matrix material Mx is, the more the current injection efficiency improves.

### Material Combination 1

When the quantum dots QD include a group II-VI compound, the second element in the matrix material Mx may include any one or more of a group I element in a higher period than a group II element included in the quantum dots QD, a group II element in a higher period than a group II element included in the quantum dots QD, and a group III element in a higher period than a group II element included in the quantum dots QD. The group II-VI compound generally indicates a compound composed of a group II element and a group VI element at a composition ratio of about 1:1. The group II-VI compound includes ZnS, ZnO, and ZnSe. For example, when the quantum dots QD include zinc (Zn), the second element may include any one or more of hydrogen (H), lithium (Li), beryllium (Be), boron (B), sodium (Na), magnesium (Mg), aluminum (Al), potassium (K), calcium (Ca), and scandium (Sc).

In an example in which the shells of the quantum dots QD include ZnO or ZnS, the matrix material Mx preferably includes LiₓBe_{y}Mg_{z}Zn_{(1-x-y-z)}O or LiₓBe_{y}Mg_{z}Zn_{(1-x-y-z)}S. In any combination, 0≤x, 0≤y, 0≤z, and 0<x+y+z≤1 are satisfied. Furthermore, in consideration of Example 1 and Example 2 described later, 0.1≤x+y+z<1 is more preferable.

In an example in which the shells of the quantum dots QD include ZnO or ZnS, the matrix material Mx also preferably includes AlₓZn₍₁₋ₓ₎O or AlₓZn₍₁₋ₓ₎S. In an example in which the shells of the quantum dots QD include ZnSe, the matrix material Mx preferably includes AlₓZn₍₁₋ₓ₎Se. In both examples, 0<x≤1 is satisfied. Further, 0.1≤x<1 is more preferable.

### Material Combination 2

When the quantum dots QD include a group III-V compound, the second element in the matrix material Mx may include any one or more of a group II element in a higher period than a group III element included in the quantum dots QD, a group III element in a higher period than a group III element included in the quantum dots QD, and a group IV element in a higher period than a group III element included in the quantum dots QD. The group III-V compound generally indicates a compound composed of a group III element and a group V element at a composition ratio of about 1:1. The group III-V compound includes AlN, GaN, and InN.

In an example in which the shells of the quantum dots QD include AlN, the matrix material Mx preferably includes BₓC_{y}Al_{(1-x-y)}N. In an example in which the shells of the quantum dots QD include GaN, the matrix material Mx preferably includes BₓC_{y}Ga_{(1-x-y)}N. In both examples, 0≤x, 0≤y, and 0<x+y≤1 are satisfied. Further, 0.1≤x+y<1 is more preferable. In this paragraph, “B” means B (boron) and “C” means C (carbon).

### Material Combination 3

When the quantum dots QD include a group I-III-VI₂ compound, the second element in the matrix material Mx may include any one or more of a group I element in a higher period than a group I element included in the quantum dots QD, a group II element in a higher period than a group I element or a group III element included in the quantum dots QD, a group III element in a higher period than a group III element included in the quantum dots QD, and a group VI element in a higher period than a group VI element included in the quantum dots QD. The group I-III-VI₂ compound generally indicates a compound composed of a group I element, a group III element, and a group VI element at a composition ratio of about 1:1:2. The Group I-III-VI₂ compound includes CuAlS₂, CuAlSe₂, CuGaS₂, AgAlS₂, AgAlSe₂, and AgGaSe₂.

In an example in which the shells of the quantum dots QD include CuAlS₂, the matrix material Mx preferably includes CuBₓAl₍₁₋ₓ₎O_{2y}S_{(2-2y)}. In an example in which the shells of the quantum dots QD include CuAlSe₂, the matrix material Mx preferably includes any one of CuBₓAl₍₁₋ₓ₎O_{2y}S_{(2-2y)}, CuBₓAl₍₁₋ₓ₎O_{2y}Se_{(2-2y)}, CuBₓGa₍₁₋ₓ₎O_{2y}S_{(2-2y)}, AgBₓAl₍₁₋ₓ₎O_{2y}S_{(2-2y)}, and AgBₓAl₍₁₋ₓ₎O_{2y}Se_{(2-2y)}. In an example in which the shells of the quantum dots QD include CuGaS₂, the matrix material Mx preferably includes any one of CuBₓAl₍₁₋ₓ₎O_{2y}S_{(2-2y)}, CuB_{X}Al_{(1-X)}O_{2y}Se_{(2-2y)}, AgBₓAl₍₁₋ₓ₎O_{2y}S_{(2-2y)}, and AgBₓAl₍₁₋ₓ₎O_{2y}Se_{(2-2y)}. In an example in which the shells of the quantum dots QD include AgAlS₂, the matrix material Mx preferably includes CuBₓAl₍₁₋ₓ₎O_{2y}S_{(2-2y)}.

In an example in which the shells of the quantum dots QD include AgAlSe₂, the matrix material Mx preferably includes any one of CuBₓAl₍₁₋ₓ₎O_{2y}S_{(2-2y)}, CuBₓAl₍₁₋ₓ₎O_{2y}Se_{(2-2y)}, and CuBₓGa₍₁₋ₓ₎O_{2y}S_{(2-2y)}. In an example in which the shells of the quantum dots QD include AgGaSe₂, the matrix material Mx preferably includes any one of CuB_{X}Al₍₁₋ₓ₎O_{2y}S_{(2-2y)}, CuBₓAl₍₁₋ₓ₎O_{2y}Se_{(2-2y)}, CuB_{X}Ga₍₁₋ₓ₎O_{2y}S_{(2-2y)}, AgBₓAl₍₁₋ₓ₎O_{2y}S_{(2-2y)}, AgBₓAl₍₁₋ₓ₎O_{2y}Se_{(2-2y)}, and AgB_{X}Ga₍₁₋ₓ₎O_{2y}S_{(2-2y)}. In any combination, 0≤x≤1, 0≤y≤1, and 0<x+y≤2 are satisfied. Further, 0.1≤x+y<2 is more preferable. “B” described in this paragraph means B (boron).

### Material Combination 4

When the quantum dots QD include a group II-IV-V₂ compound, the second element in the matrix material Mx may include any one or more of a group I element in a higher period than a group II element included in the quantum dots QD, a group II element in a higher period than a group II element included in the quantum dots QD, a group III element in a higher period than a group II element or a group IV element included in the quantum dots QD, a group IV element in a higher period than a group IV element included in the quantum dots QD, and a group V element in a higher period than a group V element included in the quantum dots QD. The group II-IV-V₂ compound generally indicates a compound composed of a group II element, a group IV element, and a group V element at a composition ratio of about 1:1:2. The group II-IV-V₂ compound includes ZnSiP₂ and CdSiP₂.

In an example in which the shells of the quantum dots QD include ZnSiP₂, the matrix material Mx preferably includes ZnCₓSi₍₁₋ₓ₎N_{2y}P_{(2-2y)}. In an example in which the shells of the quantum dots QD include CdSiP₂, the matrix material Mx preferably includes ZnCₓSi₍₁₋ₓ₎N_{2y}P_{(2-2y)} or CdCₓSi₍₁₋ₓ₎N_{2y}P_{(2-2y)}. In any combination, 0≤x≤1, 0≤y≤1, and 0<x+y≤2 are satisfied. Further, 0.1≤x+y<2 is more preferable.

### Material Combination 5

When the quantum dots QD include a group IV compound, the second element in the matrix material Mx may include a group IV element in a higher period than a group IV element included in the quantum dots QD. The group IV compound generally indicates a compound composed of plurality of kinds of group IV elements. The group IV compound includes SiC, GeC, and SnC. In an example in which the shells of the quantum dots QD include GeC, the matrix material Mx preferably includes SiC. “C” described in this paragraph means C (carbon).

### Halogen

The matrix material Mx may further contain halide ions including at least one of fluoride ions, chloride ions, bromide ions, iodide ions. The matrix material Mx may include 1 atomic % or more of halogen atoms. The concentration of halide ions in the vicinity of each of the quantum dots QD is preferably higher than the concentration of halide ions on the peripheral side from the vicinity of the quantum dots QD. For example, in the periphery of a certain quantum dot QD, a range within a distance of 1 nm from the outermost surface of the quantum dot QD may be regarded as the vicinity of the quantum dot QD. For example, the mean value of the concentration of halogen atoms within the distance of 1 nm from the outermost surface of each of the quantum dots QDs may be 10% or more, 50% or more, or 100% or more higher than the mean value of the concentration of halogen atoms at other positions.

The matrix material Mx can contain halide ions by forming the light-emitting layer EL using a quantum dot dispersion liquid containing a halogen element and the quantum dots QD.

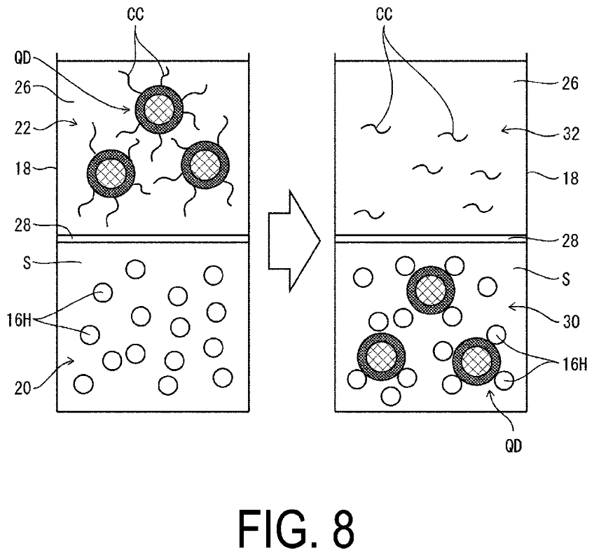

FIG. 8 includes process cross-sectional views for describing a step of substituting a ligand coordinated with a quantum dot. As illustrated in the view on the left side of FIG. 8, in the substitution step, first, a first solution 20 in which halide ions 16H are dissolved and a second solution 22 in which the quantum dots QD with which carbon chains CC as organic ligands are coordinated are dispersed are injected into a container 18. The first solution 20 includes a first solvent S in which the halide ions 16H are soluble, and the second solution 22 includes a second solvent 26 in which the carbon chains CC are soluble. For example, the second solvent 26 has a polarity different from that of the first solvent S and has a specific gravity lower than that of the first solvent S. To more clearly distinguish the boundary between the first solution 20 and the second solution 22, a separation liquid 28 having a specific gravity and polarity between those of the first solvent S and the second solvent 26 may be injected into the container 18.

The first solvent S well disperses the precursor of the matrix material Mx and the quantum dots QD with which the halide ions 16H are coordinated. Alternatively, the first solvent S may be a polar solvent having a polarity higher than a polarity of the second solvent 26. The second solvent 26 is desirably a non-polar solvent that is not miscible with the first solvent S.

The carbon chain CC may be a carbon chain to be generally used as a ligand of the quantum dots QD. The second solvent 26 is a solvent in which the carbon chains CC are soluble, and thus the quantum dots QD with which the carbon chains CC are coordinated are easily dispersed in the second solution 22. In addition, the halide ions 16H are dissolved in the first solution 20 in an excessive amount exceeding the amount of the halide ions 16H capable of being coordinated with the quantum dots QD. The concentration of the halide ions in the first solvent S is preferably 0.01 mol/l or more, and more preferably 0.1 mol/l or more.

Next, the container 18 containing the first solution 20 and the second solution 22 described above is vibrated at a high speed by a stirrer to stir the first solution 20 and the second solution 22. To improve stirring efficiency, a stirring bar may be put into the container 18. In other words, the step of stirring the first solution 20 and the second solution 22 is a step of treating the quantum dots QD with the halide ions 16H, in particular, a step of generating the quantum dots QD with which the halide ions 16H are coordinated.

Here, as described above, the first solution 20 contains an excessive amount of the halide ions 16H. In general, when two or more kinds of ligands are contained in a solution in which the quantum dots QD are dispersed, the ligands to be coordinated with the quantum dots QD are in an equilibrium state between the ligands in the solution. Thus, when the first solution 20 and the second solution 22 are stirred, at least a part of the ligands coordinated with the quantum dots QD is substituted from the carbon chains CC to the halide ions 16H.

For example, the solutions in the container 18 are stirred for at least one minute or longer. The stirring of the solutions in the container 18 may be performed at a frequency of 10 times per minute for 1 hour with the temperature of the solutions in the container 18 set to 25° C. Under such conditions, it can be said that the probability that the ligands coordinated with the quantum dots QD in the container 18 are replaced to the halide ions 16H is sufficiently high. In addition, to prevent water, oxygen, or the like in the air from being mixed with the solutions in the container 18, it is more desirable that the solutions in the container 18 are stirred in an atmosphere of nitrogen, argon, or the like.

Accordingly, by the stirring, as illustrated in the view on the right side of FIG. 8, a third solution 30 in which the quantum dots QD with which the halide ions 16H are coordinated are dispersed in the first solvent S and a fourth solution 32 in which the carbon chains CC are dissolved in the second solvent 26 are obtained in the container 18.

As described above, the quantum dots QD with which the halide ions 16H are coordinated are obtained in the third solution 30. Note that the stirring may be completed when the liquid in the container 18 is irradiated with ultraviolet light or the like and it is confirmed that the liquid layer emitting light moves from the upper side to the lower side of the container 18.

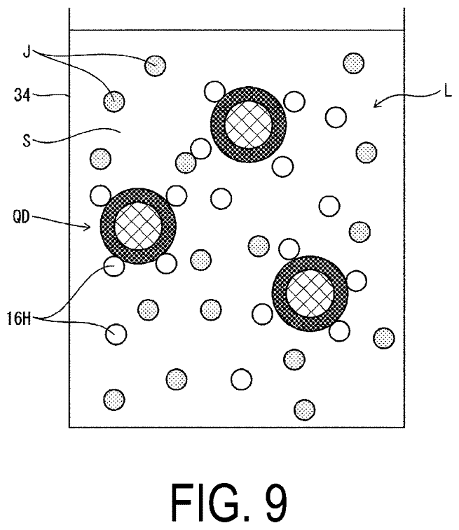

Next, a quantum dot dispersion liquid in which the quantum dots QD with which the halide ions 16H are coordinated are dispersed is synthesized. The quantum dot dispersion liquid according to the present embodiment will be described in detail with reference to FIG. 9. FIG. 9 is a schematic view illustrating a quantum dot dispersion liquid. For example, subsequent to the stirring described above, only the third solution 30 is extracted from the container 18 by a dropper or the like and injected into a container 34 illustrated in FIG. 9.

Here, a solution in which a precursor J of the matrix material Mx is dispersed in the first solvent S in advance may be injected into the container 18. Therefore, as illustrated in FIG. 8, a quantum dot dispersion liquid L in which the quantum dots QD with which the halide ions 16H are coordinated and the precursor J are dispersed in the first solvent S is synthesized.

Alternatively, when the precursor J of the matrix material Mx contains a halogen element, the matrix material Mx can contain halide ions. For example, when the matrix material Mx contains Mg, MgCl₂ (magnesium dichloride) may be used as the material containing Mg for the precursor J. When the matrix material Mx contains Li, LiCl (lithium chloride) may be used as a material containing Li for the precursor J.

### Example 1

The light-emitting element 10 according to Example 1 of the disclosure was produced.

First, a configuration was obtained in which the quantum dots QD include ZnS, the matrix material Mx includes a mixed crystal MgZnS, and the ratio of the currents I₁ and I₂ flowing through the diode elements D₁ and D₂ is I₁:I₂=10:1. When I₁:I₂=10:1, the current injection efficiency into the light-emitting diode element D₁ is about 91%.

When the ratio of currents is 10:1, the ratio of saturation currents is also 10:1. The band gaps of ZnS and MgS have been experimentally verified: Eg_{ZnS}≈3.6 eV and Eg_{MgS}≈4.4 eV. The energy gap of the mixed crystal MgZnS required to achieve a current ratio of 10:1 was calculated as Eg_{MgZnS}≈3.7 eV using Equation (4) and Equation (5). The ratio of MgS in the mixed crystal MgZnS was calculated as x_{Mg}≈0.1 using Equation (8). Under atmospheric pressure, ZnS has a wurtzite structure, MgS has a halite structure, and the mixed crystal MgZnS maintains the wurtzite structure when the ratio of MgS is from 0% to about 20%. Therefore, when x_{Mg}≈0.1, it is not necessary to consider a change in the crystal structure of the matrix material Mx.

Further, the diode coefficients of the diode elements D₁ and D₂ were both set to n=3, and the parameters in Equation (1) and Equation (2) were calculated. r≈200Ω, r₁≈69Ω, r₂≈142Ω, V₁≈5 V, and V₂≈5.2 V were obtained.

Next, according to the results, the light-emitting element 10 according to Example 1 was formed. To be specific, the anode E1 and the charge function layer F1 are formed on the substrate by a known technique, and a colloidal dispersed solution in which the quantum dots QD are dispersed is applied or printed on the charge function layer F1 to form the quantum dot layer. Next, a precursor solution of the mixed crystal MgZnS was applied onto the quantum dot layer to mineralize the quantum dot layer. In this manner, the light-emitting layer EL was formed. Then, the charge function layer F2 and the cathode E2 were formed on the light-emitting layer EL by a known technique.

In relation to the precursor solution, as a precursor of MgZnS, tertiary thiol was mixed with ZnTNT (zinc-t-nonanethiolate) and MgTNT (magnesium-t-nonanethiolate). Here, the volume ratio of ZnTNT to MgTNT was set to 1/9 or more (ZnTNT/MgTNT≥1/9). The reason why the Mg ratio in the precursor is larger than the Mg ratio in the matrix material Mx is that Mg is more likely to be consumed by a side reaction other than the main reaction, which has higher activity than Zn. As a result of the consumption of Mg by the side reaction, Mg is hardly taken into the matrix material Mx. Note that when the material containing Mg and the material containing Zn are weighed, the weight of the Mg material is preferably set 20 times or more the weight of the Zn material because the density (=mass/volume) of Mg is smaller than that of Zn.

Further, a light-emitting element of a comparative example in which the matrix material Mx contains ZnS was produced.

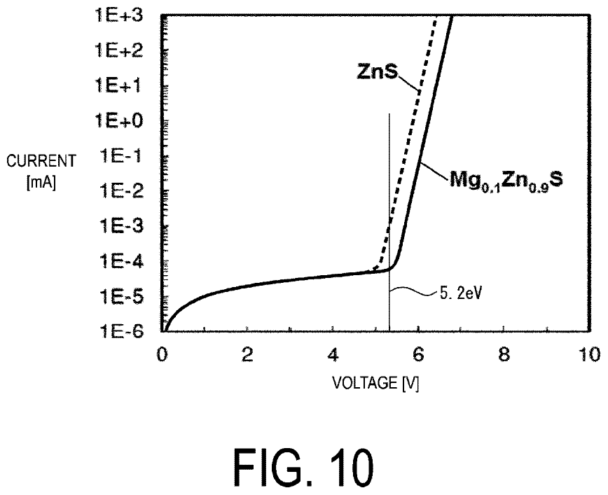

FIG. 10 is a diagram illustrating J-V characteristics of the diode element according to Example 1. In FIG. 10, the solid line indicates the relationship between the current density and the voltage (J-V characteristic) of the light-emitting diode element D₁, and the broken line indicates the J-V characteristics of the non-light-emitting diode element D₂.

From FIG. 10, it was found that when 10% of Mg was added to ZnS and Mg_{0.1}Zn_{0.9}S was used as the matrix material Mx, the current in the vicinity of the turn-on voltage was significantly suppressed as compared with the case where only ZnS was used as the matrix material Mx.

### Example 2

The light-emitting element 10 according to Example 2 of the disclosure was designed.

A configuration was obtained in which the quantum dots QD include ZnS, the matrix material Mx includes a mixed crystal LiZnS, and the ratio of the currents I₁ and I₂ flowing through the diode elements D₁ and D₂ is I₁:I₂=10:1. As a result of calculation in the same manner as in Example 1, the energy gap of the mixed crystal LiZnS required to achieve a current ratio of 10:1 was Eg_{LiZnS}≈3.7 eV. In addition, the ratio of LiS in the mixed crystal LiZnS was x_{LiS}≈0.1.

The light-emitting element 10 according to Example 2 can be produced by using a mixture obtained by mixing LiTNT (lithium t-nonanethiolate) and ZnTNT with tertiary thiol as a precursor of LiZnS.

### Example 3

The light-emitting element 10 according to Example 3 of the disclosure was designed.

A configuration was obtained in which the quantum dots QD include ZnS, the matrix material Mx includes a mixed crystal LiMgZnS, and the ratio of the currents I₁ and I₂ flowing through the diode elements D₁ and D₂ is I₁:I₂=10:1. As a result of calculation in the same manner as in Example 1, the energy gap of the mixed crystal LiMgZnS required to achieve a current ratio of 10:1 was Eg_{LiMgZnS}≈3.7 eV. In addition, the ratio of LiS and MgS in the mixed crystal LiMgZnS was x_{Lis}+x_{Mgs}≈0.1.

From Examples 1 to 3, it was estimated that the band gap of the matrix material Mx is larger than the band gap of the quantum dots QD, and the difference therebetween is preferably 0.1 eV or more. Here, the band gap of the quantum dots QD may be the band gap of the cores of the quantum dots QD, or the band gap of the shells of the quantum dots QD. In addition, when the quantum dots QD include the compound AC composed of the element A and the element C and the matrix material Mx includes the mixed crystal ABC in which the compound BC composed of the element B and the element C is mixed with the compound AC, it was estimated that the ratio of the compound BC in the mixed crystal ABC is preferably 0.1 or more. The “element A”, the “element B” and the “element C” described in this paragraph are merely tentative names of three elements.

### Modified Example

The materials used for the quantum dots QD and the matrix material Mx may be simply determined so that the band gap of the matrix material Mx is larger than the band gap of the quantum dots QD. This modified example includes a configuration in which the quantum dots QD do not include the first element, a configuration in which the matrix material Mx does not include the second element, and a configuration in which the matrix material Mx is composed of only one element. The light-emitting layer EL according to this modified example is located between the anode E1 and the cathode E2, and includes the plurality of quantum dots QD and the matrix material Mx having a band gap larger than a band gap of the plurality of quantum dots QD and including the plurality of quantum dots QD.

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

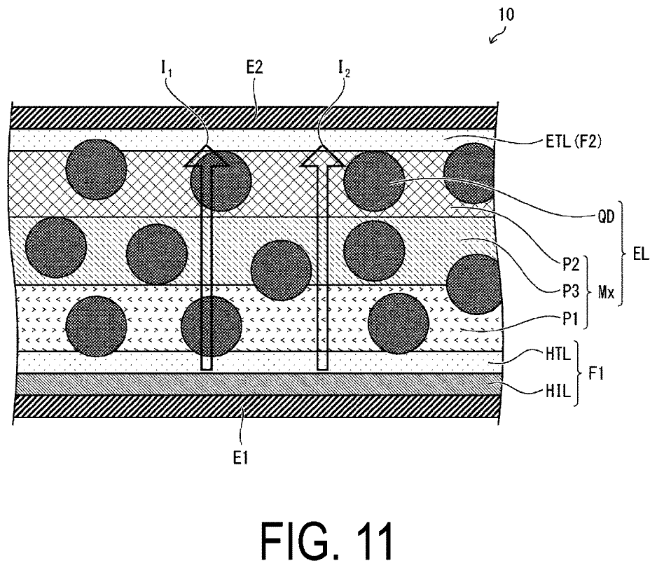

FIG. 11 is a cross-sectional view illustrating a configuration example of the light-emitting element according to an embodiment of the disclosure. As illustrated in FIG. 11, the matrix material Mx according to the present embodiment includes a first portion P1 located on the anode E1 side and a second portion P2 located on the cathode E2 side. The matrix material Mx may include a third portion P3 between the first portion P1 and the second portion P2.

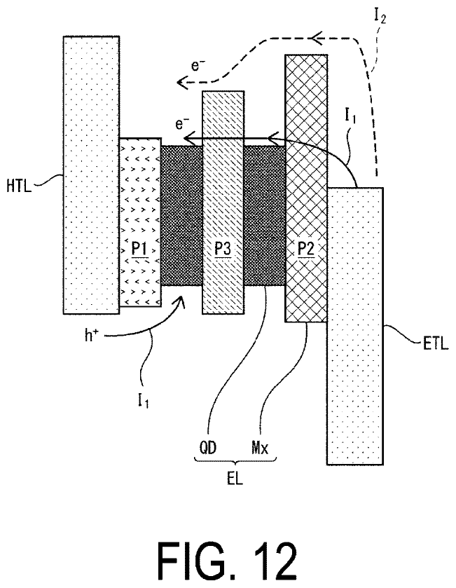

FIG. 12 is a schematic view illustrating an example of a band structure of the light-emitting layer illustrated in FIG. 11. In FIG. 12, the HOMO and LUMO of each of the hole transport layer HTL, the matrix material Mx, the quantum dots QD, and the electron transport layer ETL, and the band gap therebetween are indicated by rectangles. As illustrated in FIG. 12, the band gap in the first portion P1 of the matrix material Mx is smaller than the band gap in the second portion P2 of the matrix material Mx.

The magnitude of the band gap in the matrix material Mx preferably increases stepwise or continuously from the anode E1 side toward the cathode E2 side. The band gap in the third portion P3 of the matrix material Mx is preferably larger than the band gap in the first portion P1 of the matrix material Mx and smaller than the band gap in the second portion P2 of the matrix material Mx.

### Third Embodiment

Another embodiment of the disclosure will be described below.

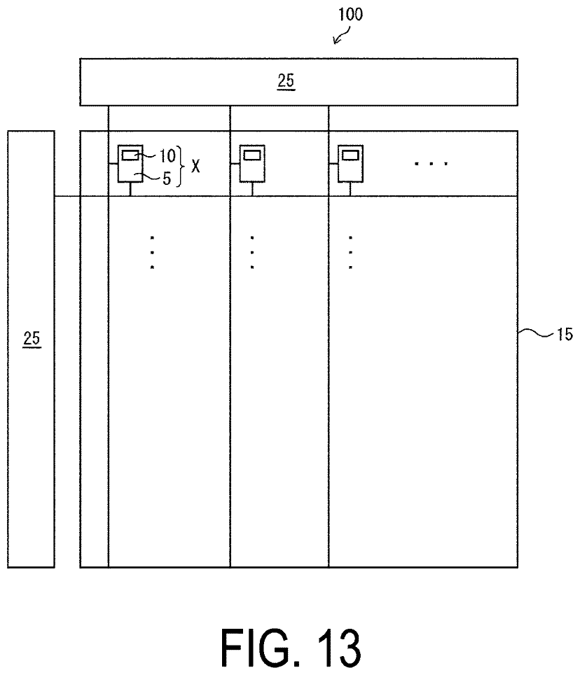

FIG. 13 is a plan view illustrating a configuration example of a light-emitting device according to an embodiment of the disclosure. As illustrated in FIG. 13, a light-emitting device 100 includes a display portion 15 including a plurality of subpixels X and a driver circuit 25 that drives the display portion 15. For example, the subpixel X includes the light-emitting element 10 described in the first or second embodiment and a pixel circuit 5. The light-emitting device 100 may be a display device or an illumination device.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
an anode and a cathode; and
a light-emitting layer located between the anode and the cathode,
wherein the light-emitting layer includes
a plurality of quantum dots including a first element that is a metal element, and
a matrix material including the plurality of quantum dots and composed of two or more kinds of elements to include a second element that is located in a higher period than the first element and is not included in the plurality of quantum dots.

2. The light-emitting element according to claim 1,
wherein the matrix material fills a space between the plurality of quantum dots.

3. The light-emitting element according to claim 1,
wherein the light-emitting layer includes a quantum dot group including the plurality of quantum dots, and
the matrix material fills a region other than the quantum dot group.

4-6. (canceled)

7. The light-emitting element according to claim 1,
wherein a difference between a number of valence electrons of the first element and a number of valence electrons of the second element is 1.

8. The light-emitting element according to claim 1,
wherein the matrix material includes a continuous film of a mixed crystal composed of the two or more kinds of elements.

9. The light-emitting element according to claim 1,
wherein the matrix material includes a continuous film of an inorganic compound.

10. The light-emitting element according to claim 1,
wherein a band gap of the matrix material is larger than a band gap of the plurality of quantum dots.

11. The light-emitting element according to claim 1,
wherein the plurality of quantum dots include a group II-VI compound, and
the second element includes any one or more of the following:
a group I element in a higher period than a group II element included in the plurality of quantum dots;
a group II element in a higher period than a group II element included in the plurality of quantum dots; and
a group III element in a higher period than a group II element included in the plurality of quantum dots.

12. The light-emitting element according to claim 11,
wherein shells of the plurality of quantum dots include ZnO or ZnS, and
the matrix material includes LiₓBe_{y}Mg_{z}Zn_{(1-x-y-z)}O or LiₓBe_{y}Mg_{z}Zn_{(1-x-y-z)}S,
in which 0≤x, 0≤y, 0≤z, and 0<x+y+z≤1 are satisfied.

13. The light-emitting element according to claim 12,
wherein 0.1≤x+y+z<1 is satisfied.

14. The light-emitting element according to claim 11,
wherein shells of the plurality of quantum dots include ZnO or ZnS, and the matrix material includes AlₓZn₍₁₋ₓ₎O or AlₓZn₍₁₋ₓ₎S, or
shells of the plurality of quantum dots include ZnSe, and the matrix material includes AlₓZn₍₁₋ₓ₎Se,
in which 0<x≤1 is satisfied.

15. The light-emitting element according to claim 14,
wherein 0.1≤x<1 is satisfied.

16. The light-emitting element according to claim 1,
wherein the plurality of quantum dots include a group III-V compound, and
the second element includes any one or more of the following:
a group II element in a higher period than a group III element included in the plurality of quantum dots;
a group III element in a higher period than a group III element included in the plurality of quantum dots; and
a group IV element in a higher period than a group III element included in the plurality of quantum dots.

17-18. (canceled)

19. The light-emitting element according to claim 1,
wherein the plurality of quantum dots include a group I-III-VI₂ compound, and
the second element includes any one or more of the following:
a group I element in a higher period than a group I element included in the plurality of quantum dots;
a group II element in a higher period than a group I element or a group III element included in the plurality of quantum dots;
a group III element in a higher period than a group III element included in the plurality of quantum dots; and
a group VI element in a higher period than a group VI element included in the plurality of quantum dots.

20-21. (canceled)

22. The light-emitting element according to claim 1,
wherein the plurality of quantum dots include a group II-IV-V₂ compound, and
the second element includes any one or more of the following:
a group I element in a higher period than a group II element included in the plurality of quantum dots;
a group II element in a higher period than a group II element included in the plurality of quantum dots;
a group III element in a higher period than a group II element or a group IV element included in the plurality of quantum dots;
a group IV element in a higher period than a group IV element included in the plurality of quantum dots; and
a group V element in a higher period than a group V element included in the plurality of quantum dots.

23-24. (canceled)

25. The light-emitting element according to claim 1,
wherein the plurality of quantum dots include GeC, and
the matrix material includes SiC.

26. A light-emitting element comprising:
an anode and a cathode; and
a light-emitting layer located between the anode and the cathode,
wherein the light-emitting layer includes
a plurality of quantum dots, and
a matrix material including the plurality of quantum dots and having a band gap larger than a band gap of the plurality of quantum dots, and
a band gap in a first portion of the matrix material located on an anode side is smaller than a band gap in a second portion of the matrix material located on a cathode side.

27-28. (canceled)

29. The light-emitting element according to claim 26,
wherein the matrix material further includes a halogen atom, and
the matrix material includes 1 atomic % or more of halogen atoms.

30. (canceled)

31. A light-emitting element comprising:
an anode and a cathode; and
a light-emitting layer located between the anode and the cathode,
wherein the light-emitting layer includes a plurality of quantum dots, and a matrix material including the plurality of quantum dots and having a band gap larger than a band gap of the plurality of quantum dots,
the matrix material further includes a halogen atom, and
a mean value of a concentration of halogen atoms at a position within a distance of 1 nm from an outermost surface of the plurality of quantum dots is 10% or more higher than a mean value of a concentration of halogen atoms at other positions.

32. (canceled)

33. A light-emitting device comprising:
the light-emitting element according to claim 1.
